(19) United States
(12) Patent Application Publication
(10) Pub. No.: US 2022/0112622 A1
(43) Pub. Date: Apr. 14, 2022

(54) PRODUCTION APPARATUS FOR GALLIUM OXIDE CRYSTAL

(71) Applicant: Fujikoshi Machinery Corp., Nagano (JP)

(72) Inventors: Keigo HOSHIKAWA, Nagano (JP); Takumi KOBAYASHI, Nagano (JP); Yoshio OTSUKA, Nagano (JP); Toshinori TAISHI, Nagano (JP)

(21) Appl. No.: 17/494,132

(22) Filed: Oct. 5, 2021

(30) Foreign Application Priority Data
Oct. 12, 2020 (JP) 2020-172014

(51) Int. Cl. C30B 11/00; C30B 29/16

(52) U.S. Cl. CPC C30B 11/003; C30B 29/16

(57) ABSTRACT

There is provided a production apparatus of a gallium oxide crystal using a resistance heater, the heater provided therein being capable of being provided at a low cost and capable of suppressing deformation and breakage due to heat. The production apparatus for a gallium oxide crystal according to one or more aspects of the present invention includes a furnace body constituted by a heat resistant material, a crucible disposed in the furnace body, and a heater disposed around the crucible, the heater being a resistance heater including a heating part and a conductive part having a larger diameter than the heating part connected to each other, the heating part being constituted by a material having heat resistance to 1,850° C., the conductive part being constituted by a material having heat resistance to 1,800° C.

### CROSS-REFERENCE TO RELATED APPLICATION

This application is based upon and claims the benefit of priority of the prior Japanese Patent Application No. 2020-172014, filed on Oct. 12, 2020, and the entire contents of which are incorporated herein by reference.

### TECHNICAL FIELD

The present invention relates to a production apparatus for a gallium oxide crystal.

### BACKGROUND ART

Apparatuses for producing a single crystal of gallium oxide (which may be hereinafter referred to as a “gallium oxide crystal” in some cases) receiving attention as a wide gap semiconductor for a power device have been known. The apparatuses produce a gallium oxide crystal by the method, for example, the VB method (vertical Bridgman method), the VGF method (vertical gradient freeze method), the HB method (horizontal Bridgman method), or the HGF method (horizontal gradient freeze method).

In the VB method and the VGF method, for example, a vertical temperature gradient is used. Specifically, in the production apparatus for a gallium oxide crystal described in PTL 1 (JP-A-2017-193466), a crucible having a material of gallium oxide (crystal material) housed therein is disposed in a furnace provided as a VB furnace, and plural heaters extended in the vertical direction are disposed around the crucible. A vertical temperature gradient with a higher temperature in the upper portion and a lower temperature in the lower portion is provided in the vicinity of the crucible in the furnace with the heaters. In heating the crucible with the heaters, the crystal material is melted. The crucible is then descended to crystallize the molten material from the lower side, resulting in a gallium oxide crystal.

The heater used may be a high frequency induction heater or a resistance heater. The resistance heater among these has a heating part and a conductive part, and the heating part is electrified through the conductive part connected to an external electric power source, so that the heating part generates heat to heat the crucible.

### SUMMARY OF INVENTION

### Technical Problem

Gallium oxide has an extremely high melting point of approximately 1,795° C. for β-Ga₂O₃, and at the time when the crucible is heated with the resistance heater until the crystal material is melted, the temperature of the heater reaches around 1,850° C. Accordingly, the entire heater has been constituted by a material having heat resistance to approximately 1,850° C.

However, even with the constitution, the heater may suffer progressing deformation and breakage due to the time degradation caused by heating in the repeated use of the apparatus, and therefore the heater is necessarily exchanged. In consideration of the increase in size of the structure of the entire apparatus including the heaters due to the increase in size of crystals to be produced in future, there is an increasing demand of a heater that is difficult to suffer deformation and breakage due to heat provided at a lower cost since the heater is relatively expensive.

### Solution to Problem

The present invention has been made in view of the circumstances, and one or more aspects thereof are directed to a production apparatus of a gallium oxide crystal using a resistance heater, the heater provided therein being capable of being provided at a low cost and capable of suppressing deformation and breakage due to heat.

One or more aspects of the present invention will be described below.

A production apparatus for a gallium oxide crystal according to one aspect of the present invention includes a furnace body constituted by a heat resistant material, a crucible disposed in the furnace body, and a heater disposed around the crucible, the heater being a resistance heater including a heating part and a conductive part having a larger diameter than the heating part connected to each other, the heating part being constituted by a material having heat resistance to 1,850° C., the conductive part being constituted by a material having heat resistance to 1,800° C.

According to the aspect, the heating part generating heat reaching nearly 1,850° C. is constituted by a material having heat resistance to 1,850° C. to suppress deformation and breakage thereof due to heat, whereas the conductive part not reaching the high temperature as in the heating part is constituted by a relatively not expensive material having heat resistance to 1,800° C., and thereby the total material cost of the heater can be reduced.

It is preferred that the heater includes the heating part that is connected to the conductive part via a connecting part formed to have a diameter that is larger than the heating part and smaller than the conductive part, constituted by a material having heat resistance to 1,850° C. According to the structure, the heating part and the conductive part are connected to each other via the connecting part constituted by a material having the same heat resistance to 1,850° C. as the heating part, formed to have a larger diameter than the heating part, and thereby the portion of the heating part from the base end to the connecting site to the conductive part, i.e., the portion thereof positioned in the maximum temperature zone in the furnace body most tending to be a high temperature, can be protected from heat. As a result, the deformation and breakage of the heater can be further suppressed.

It is preferred that the heater has a ratio of a diameter (x) of the heating part, a diameter (y) of the connecting part, and a diameter (z) of the conductive part (x:y:z) that satisfies 3≤x≤9, 4≤y≤12, and 6≤z≤18 (provided that x<y<z), and more preferably y≤3x, z≤2y, and z≤4x (provided that x<y<z). It is preferred that the heater is formed of molybdenum disilicide (MoSi₂).

It is possible that the heater is provided in a linear shape from side view, in such a manner that the conductive part penetrates through an upper portion of the furnace body and is provided in the vertical direction in the furnace body, and the heating part is extended in the vertical direction at a tip of the conductive part in the furnace body. In alternative, it is possible that the heater is provided in an L-shape from side view, in such a manner that the conductive part penetrates through a side part of the furnace body and is bent in the vertical direction in the furnace body, and the heating part is extended in the vertical direction at a tip of the conductive part in the furnace body.

It is preferred that the heater includes two conductive parts connected to the heating part at tips thereof formed in a U-shape, the heating part has a diameter of 3 to 9 mm, and the heating part has a bending width of less than 40 mm. According to the structure, the members for mounting the heater can be prevented from suffering interference therebetween, by decreasing the bending width of the heating part. Furthermore, the number of the heaters can be increased without distancing the heaters from the crucible.

### Advantageous Effects of Invention

According to one or more aspects of the present invention, a production apparatus of a gallium oxide crystal using a resistance heater that is capable of being provided at a low cost and capable of suppressing deformation and breakage due to heat can be achieved.

### BRIEF DESCRIPTION OF DRAWINGS

FIGS. 1A and 1B each are a schematic illustration (vertical cross sectional view) showing one example of a production apparatus of a gallium oxide crystal according to one embodiment of the present invention.

FIG. 2 is a schematic illustration (front view) showing one example of the heater of the production apparatus of a gallium oxide crystal shown in FIGS. 1A and 1B.

FIGS. 3A and 3B each are an explanatory illustration (cross sectional view on line III-III in FIG. 1A) for showing the bending width of the heating part of the heater of the production apparatus of a gallium oxide crystal shown in FIGS. 1A and 1B.

FIGS. 4A and 4B each are a photograph of the heaters in Example 1 after the production of a β-Ga₂O₃ crystal.

FIGS. 5A and 5B each are a photograph of the heaters in Example 2 after the production of a β-Ga₂O₃ crystal.

FIG. 6 is a photograph of the heaters in Reference Example after the production of a β-Ga₂O₃ crystal.

### DESCRIPTION OF EMBODIMENTS

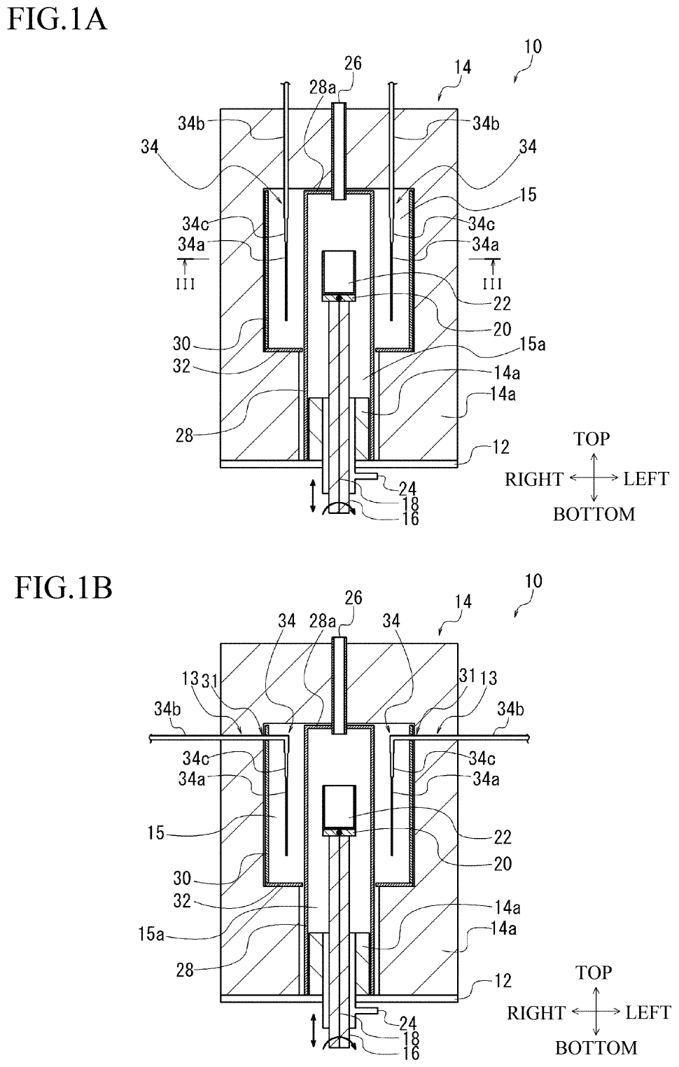

Embodiments of the present invention will be described in detail below with reference to the drawings. FIGS. 1A and 1B each are a schematic illustration (vertical cross sectional view) showing one example of a production apparatus of a gallium oxide crystal 10 according to the present embodiment. FIG. 1A shows the production apparatus of a gallium oxide crystal 10 having a heater 34 in a linear shape from side view, and FIG. 1B shows the production apparatus of a gallium oxide crystal 10 having a heater 34 in an L-shape from side view. For the sake of visibility, only two heaters 34 on the right and left sides are shown among the many heaters generally provided.

The production apparatus of a gallium oxide crystal 10 according to the present embodiment is a production apparatus of a gallium oxide crystal (single crystal) that melts a material of a gallium oxide crystal by heating a crucible 22 (in a furnace body 14) with the heaters 34 and performs crystal growth through supercooling caused by cooling at a prescribed rate as a driving force. In the following description, an example in which the furnace body 14 of the production apparatus of a gallium oxide crystal 10 is a VB furnace is described, but the furnace body 14 may be, for example, a VGF furnace, an HB furnace, or an HGF furnace.

The production apparatus of a gallium oxide crystal 10 shown in FIGS. 1A and 1B has the furnace body 14 on a base substrate 12. The furnace body 14 includes plural ring members having a prescribed height formed of a heat resistant material 14a, which are laminated in the vertical direction to form a cylinder shape, having a furnace space 15 formed therein (the laminated structure of the ring members is not shown in the figures). A recessed portion 15a recessed around the center axis of the furnace body 14 is formed on the bottom surface of the furnace space 15.

A crucible bearing 16 is extended in the vertical direction along the center axis of the furnace body 14, penetrating the base substrate 12 and the bottom portion of the furnace body 14, reaching around the height center of the furnace space 15 through the recessed portion 15a. The crucible bearing 16 is provided freely vertically movably and freely rotatably with a driving mechanism, which is not shown in the figures (see the arrows in FIGS. 1A and 1B). A thermocouple 18 is disposed in the crucible bearing 16, so as to enable to measure the temperature of the crucible 22. The crucible bearing 16 is also formed of a heat resistant material.

An adapter 20 for supporting the crucible 22 is provided on the crucible bearing 16 (i.e., on the upper end of the crucible bearing 16), and the crucible 22 is provided on the adapter 20. The crucible 22 for growing a β-Ga₂O₃ crystal is preferably formed of a platinum-based alloy, such as a platinum-rhodium (Pt—Rh) alloy having a rhodium (Rh) content of 10 to 30% by weight. The adapter 20 is also formed of a heat resistant material.

The periphery of the crucible bearing 16 is surrounded by the ring members formed of the heat resistant material 14a from the bottom surface of the recessed portion 15a to around the height center, and the lower portion of the furnace body 14 is thermally insulated. The crucible 22 can be taken in and out from the furnace body 14 in such a manner that the ring members are detached to open the bottom of the recessed portion 15a, or the ring members constituting the laminated structure of the furnace body 14 is detached to the necessary height to open the furnace space 15 (which are not shown in the figures).

An inlet pipe 24 is provided in the bottom of the furnace body 14 to connect the interior and the exterior of the furnace body 14. An exhaust pipe 26 is provided in the upper portion of the furnace body 14 to connect the interior and the exterior of the furnace body 14. According to the structure, the interior of the furnace body 14 may be made to be an air atmosphere, but may be an oxidizing atmosphere by actively introducing a prescribed gas through the inlet pipe 24.

A furnace core pipe 28 surrounding the crucible 22 and the crucible bearing 16 is provided in the furnace body 14. The furnace core pipe 28 is extended from the bottom surface of the recessed portion 15a to the uppermost surface of the furnace space 15, and a top board 28a is provided on the upper portion thereof, so as to cover the side and the top of the crucible 22 and the crucible bearing 16 (provided that the exhaust pipe 26 penetrates through the top board 28a). The crucible 22 and the heater 34 can be segregated from each other with the furnace core pipe 28. Accordingly, even if a part of the heater 34 is melted at a high temperature, impurities can be prevented from being mixed into the crucible 22 (i.e., into the gallium oxide crystal to be formed).

A furnace pipe 30 in a cylinder shape surrounding the furnace core pipe 28 is provided in the furnace body 14. The furnace tube 30 is extended from the bottom surface to the uppermost surface of the furnace space 15, so as to cover the side of the furnace core pipe 28 from around the height center to the upper portion thereof. A supporting member 32 in a ring shape is provided on the bottom surface of the furnace space 15 to support the furnace pipe 30. The furnace pipe 30 can block between the heater 34 described later and the heat resistant material 14a constituting the outer wall of the furnace space 15, so as to prevent the heat resistant material 14a from suffering sintering, deformation, and cracking due to heat. Furthermore, the heat from the heater 34 can be reflected thereby to the side of the furnace core pipe 28 to heat the furnace space 15, and thereby the heat can be used without waste. The furnace core pipe 28 and the furnace pipe 30 are also formed of a heat resistant material.

The heater 34 is provided between the furnace core pipe 28 and the furnace pipe 30 in the furnace body 14. The heater 34 is a resistance heater having a heating part 34a and a conductive part 34b, and has such a structure that the heating part 34a is electrified through the conductive part 34b, and thereby the heating part 34a generates heat at a high temperature. The heater 34 (including the heating part 34a and the conductive part 34b) is provided in the furnace body 14, and a part of the conductive part 34b penetrates through the furnace body 14 (heat resistant material 14a) and is connected to an external electric power source outside the furnace body 14 (the external electric power source is not shown in the figures).

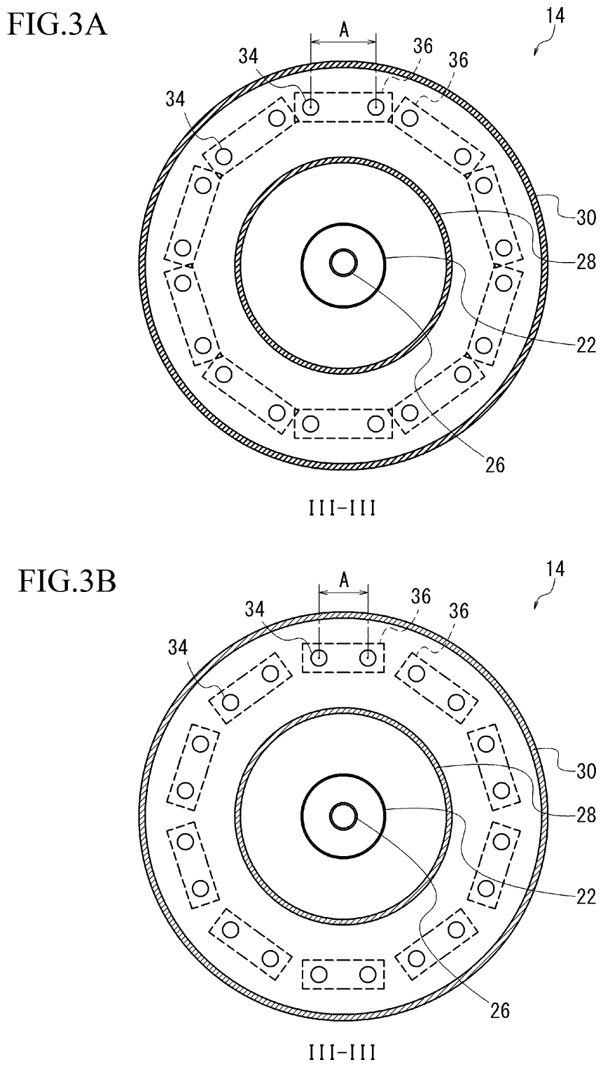

More specifically, the heater 34 shown in FIG. 1A is provided in a linear shape from side view, in such a manner that the conductive part 34b penetrates through the upper portion of the furnace body 14 and is provided in the vertical direction in the furnace body 14, and the heating part 34a is extended in the vertical direction at the tip of the conductive part 34b in the furnace body 14. The heater 34 shown in FIG. 1B is provided in an L-shape from side view, in such a manner that the conductive part 34b penetrates through the side part of the furnace body 14 and is bent in the vertical direction in the furnace body 14, and the heating part 34a is extended in the vertical direction at the tip of the conductive part 34b in the furnace body 14. Only two heaters 34 are shown in FIGS. 1A and 1B, but as shown in FIG. 3, plural heaters (herein 10 heaters 34 each having a U-shape tip) are generally provided to surround in a circle the crucible 22 positioned on the center axis in the furnace body 14 (provided that the number of the heaters 34 is not particularly limited). The disposition of the heaters 34 enables the heating parts 34a extended in the vertical direction around the crucible 22, and thereby a temperature gradient in the vertical direction with a higher temperature in the upper portion and a lower temperature in the lower portion can be formed around the crucible in the furnace body 14.

In the case where the heater 34 in an L-shape from side view shown in FIG. 1B is applied, for example, a through hole 13 through which the conductive part 34b penetrates may be formed in such a manner that in the laminated structure of the ring members constituting the furnace body 14, a semicircular groove is provided on each of the lower surface of the upper ring member and the upper surface of the lower ring member, and the semicircular grooves are butted each other. Similarly, a through hole 31 may be formed in the furnace pipe 30 in such a manner that the furnace pipe 30 is provided to have a laminated structure of ring members. According to the structure, the conductive part 34b can be mounted on the furnace body 14 and the furnace pipe 30 by penetrating through the through hole 13 of the furnace body 14 and the through hole 31 of the furnace pipe 30, i.e., by holding with the upper and lower ring members of each of the furnace body 14 and the furnace pipe 30.

The heater 34 having a particular structure in the present embodiment will be described in more detail below. The heater 34 has a structure including the heating part 34a and the conductive part 34b having a larger diameter than the heating part 34a connected to each other. The heating part 34a and the conductive part 34b are formed of the same material or substantially the same material, and the heating part 34a that generates heat at a high temperature through electrification and the conductive part 34b that supplies electric current to the heating part 34a are divided in function with the difference in electric resistance caused by the difference in diameter. Preferred examples of the material constituting the heater 34 (including the heating part 34a and the conductive part 34b) include molybdenum disilicide (MoSi₂).

In the heater 34 according to the present embodiment, the heating part 34a is constituted by a material having heat resistance to 1,850° C., and the conductive part 34b is constituted by a material having heat resistance to 1,800° C. At the time when the heating part 34a is electrified until a material of a gallium oxide crystal, such as a sintered body of β-Ga₂O₃, and a part of a seed crystal are melted in the furnace body 14, the temperature of the heating part 34a reaches nearly 1,850° C. (as the melting point of β-Ga₂O₃ is approximately 1,795° C.). Accordingly, the deformation and breakage of the heating part 34a due to heat can be suppressed by constituting the heating part 34a by a material having heat resistance to 1,850° C. On the other hand, the conductive part 34b, which does not reach such a high temperature as the heating part 34a, is constituted by a relatively inexpensive material having heat resistance to 1,800° C., and thereby the total material cost of the heater 34 can be reduced.

The heater 34 according to the present embodiment may include the heating part 34a that is connected to the conductive part 34b via a connecting part 34c formed to have a diameter that is larger than the heating part 34a and smaller than the conductive part 34b, constituted by a material having heat resistance to 1,850° C. In the furnace body 14, which is a VB furnace, the heating parts 34a are extended in the vertical direction around the crucible 22, and thereby a temperature gradient in the vertical direction with a higher temperature in the upper portion and a lower temperature in the lower portion is formed around the crucible in the furnace body 14. Accordingly, in the heater 34, the portion from the base end to the connecting site to the conductive part 34b of the heating part 34a is positioned in the maximum temperature zone in the furnace body 14 and most tends to be a high temperature. By connecting the heating part 34a and the conductive part 34b via the connecting part 34c constituted by a material having heat resistance to 1,850° C. as similar to the heating part 34a, while having a larger diameter than the heating part 34a, the portion from the base end to the connecting site to the conductive part 34b of the heating part 34a can be protected from heat. As a result, the deformation and breakage of the heater 34 can be further suppressed.

The diameters of the conductive part 34b, the connecting part 34c, and the heating part 34a are decreased in this order, and the heating part 34a can generate heat at a high temperature by electrifying the heating part 34a with an external electric power source via the conductive part 34b and further via the connecting part 34c. It is preferred that the heater 34 has a ratio of the diameter (x) of the heating part 34a, the diameter (y) of the connecting part 34c, and the diameter (z) of the conductive part 34b (x:y:z) that satisfies 3≤x≤9, 4≤y≤12, and 6≤z≤18 (provided that x<y<z), and more preferably the ratio (x:y:z) satisfies 3≤x≤9, 6≤y≤12, and 9≤z≤18 (provided that x<y<z), or the ratio preferably satisfies y≤3x, z≤2y, and z≤4x (provided that x<y<z). Specific examples of the ratio include “x=3, y=6, z=9”, “x=3, y=6, z=12”, “x=3, y=9, z=12”, “x=4, y=6 z=9”, “x=4, y=9 z=12”, “x=6, y=9 z=12”, “x=6, y=9, z=18”, “x=6, y=12, z=18”, and “x=9, y=12, z=18”. However, although the heater 34 can be produced at a lower cost than ever before according to the present embodiment, the heater 34 is generally expensive, and the production and the appropriate test of various combinations of the heaters 34 as above are not practical due to the excessive economical cost therefor. Accordingly, in the examples described later, a heater 34 with “x=6, y=9, z=12” was used (Example 2).

The term “diameter” herein means the diameter on the cross section. The conductive part 34b, the connecting part 34c, and the heating part 34a with different materials may be connected through welding or the like.

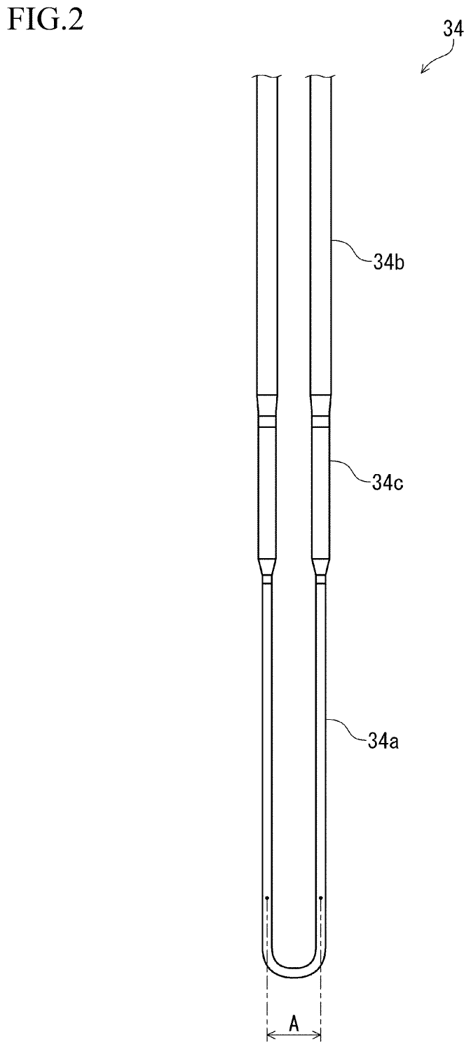

As shown in FIG. 2, the heater 34 may include two conductive parts 34b connected to the heating part 34a at tips thereof formed in a U-shape, and the heating part 34a may have a prescribed bending width (i.e., the distance between the centers of the heating part 34a shown by the symbol A in the figure). The heater 34 according to the present embodiment has such a feature that the bending width A of the heating part 34a is small.

FIGS. 3A and 3B each are a cross sectional view on line III-III in FIG. 1A as an explanatory illustration for showing the bending width A. FIGS. 3A and 3B show only the part inside the furnace pipe 30, which is required for the explanation. As described above, the crucible 22 (crucible bearing 16) is disposed on the center axis in the furnace body 14, and the plural heaters 34 are disposed to surround in a circle the crucible 22. As shown in FIG. 3A, in the case where the bending width A of the heating part 34a is large, members 36 for mounting the heaters 34 (for example, members for fixing the heaters 34 to the furnace body 14 (heat resistant material 14a)) interfere with each other. In this case, for avoiding the interference, it is necessary to deviate the heater 34 outward from the center axis with the crucible 22 positioned thereon or to decrease the number of the heaters 34, which may result in issues including the prolongation of the heating time and the deterioration of the quality of the crystal formed. In view of the circumstances, in the present embodiment as shown in FIG. 3B, the bending width A of the heating part 34a is reduced to prevent the members 36 for mounting the heaters 34 from interfering with each other. Furthermore, the number of the heaters 34 can be increased without distancing from the crucible 22.

Specifically, for example, in the case where the heating part 34a has a diameter of 3 to 9 mm, the bending width A of the heating part 34a is preferably less than 40 mm, and more preferably approximately 30 mm.

### EXAMPLES

A β-Ga₂O₃ crystal was tried to grow with the production apparatus of a gallium oxide crystal 10 according to the present embodiment having the furnace body 14 provided as a VB furnace. The heaters 34 as resistance heaters having U-shape from front view were formed in a linear shape from side view as shown in FIG. 1A, and eight heaters were disposed at regular intervals to surround in a circle the crucible 22 in the furnace body 14. The heaters 34 used in Examples had the following structures.

The heater 34 in Example 1 was a resistance heater (produced by JX Nippon Mining & Metals Corporation) having a two-part structure (including the heating part 34a and the conductive part 34b) formed of molybdenum disilicide (MoSi₂), in which the heating part 34a was formed of a material of 1900 grade and had a diameter of 6 mm, and the conductive part 34b was formed of a material of 1800 grade and had a diameter of 12 mm.

The heater 34 in Example 2 was a resistance heater (produced by JX Nippon Mining & Metals Corporation) having a three-part structure (including the heating part 34a, the connecting part 34c, and the conductive part 34b) formed of molybdenum disilicide (MoSi₂), in which the heating part 34a was formed of a material of 1900 grade and had a diameter of 6 mm, the connecting part 34c was formed of a material of 1900 grade and had a diameter of 9 mm, and the conductive part 34b was formed of a material of 1800 grade and had a diameter of 12 mm.

The 1900 grade means a standard with heat resistance to 1,850° C., and the 1800 grade means a standard with heat resistance to 1,800° C.

A seed crystal and a sintered body of β-Ga₂O₃ (crystal material) were placed in a crucible 22 (diameter: 100 mm) formed of a Pt—Rh alloy having a composition containing 80% by weight of Pt and 20% by weight of Rh, and melted in the furnace body 14 in an air atmosphere at 1,800° C. or more set to have a temperature distribution with a temperature gradient of 2 to 10° C./cm in the vicinity of the melting point of β-Ga₂O₃ (approximately 1,750° C.). Subsequently, unidirectional solidification was performed by the combination of the descending movement of the crucible 22 and the temperature decrease in the furnace body 14. Thereafter, the cooled crucible 22 was released off to take out the grown crystal. After repeating the production of a 4-inch size β-Ga₂O₃ crystal prescribed time in this manner, the heaters 34 were cooled, and the condition thereof was confirmed.

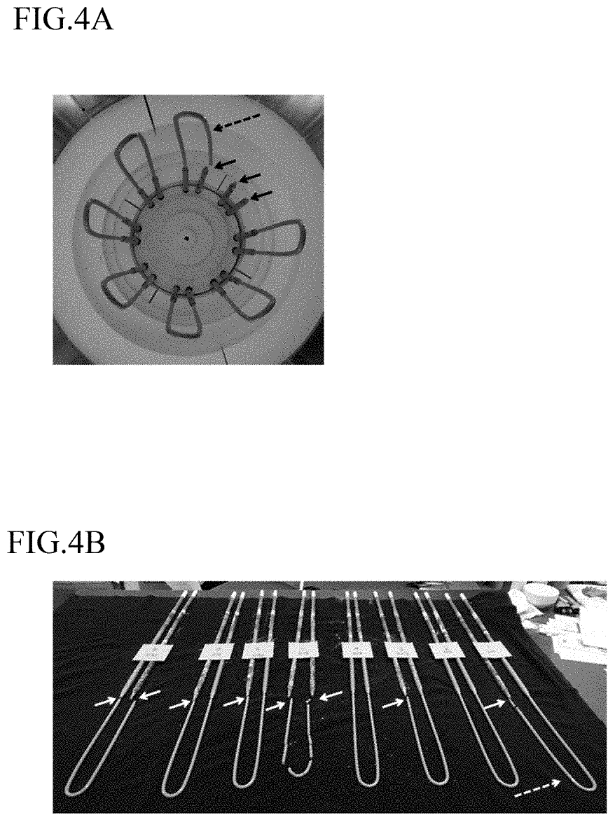

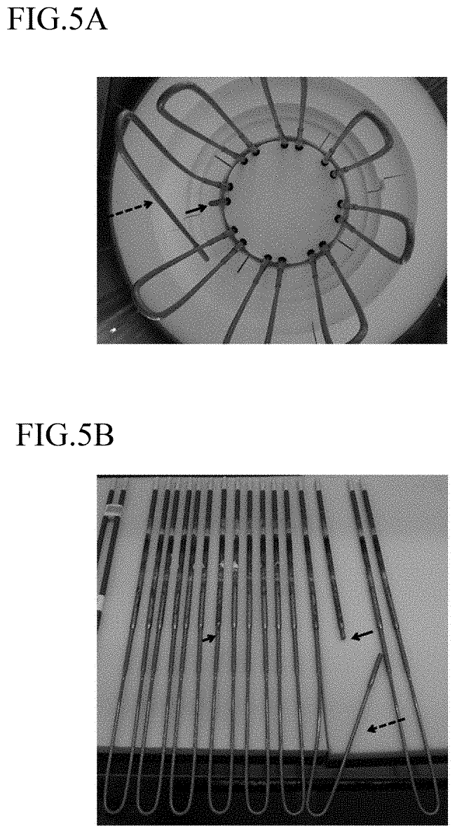

FIGS. 4A and 4B show the heaters 34 after the growth of a β-Ga₂O₃ crystal in Example 1, and FIGS. 5A and 5B show the heaters 34 after the growth of a β-Ga₂O₃ crystal in Example 2. FIGS. 4A and 5A show the state where the heaters are disposed in the furnace body 14, and FIGS. 14B and 1B show the state where the heaters are taken out from the furnace body 14. The broken site is shown by the solid line arrow, and the deformed site is shown by the dashed line arrow. In the description herein, the breakage frequency means the number of the heating parts 34a suffering breakage among the 16 heating parts 34a (herein the one U-shape heating part 34a is counted as two), and the deformation frequency means the number of heaters 34 suffering deformation among the 8 heaters 34.

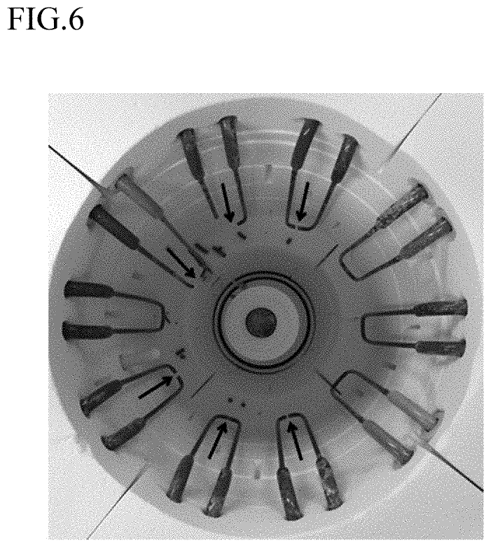

The heater 34 in Reference Example was an ordinary resistance heater (produced by Sandvik AB) formed of molybdenum disilicide (MoSi₂), in which the entirety (including the heating part 34a and the conductive part 34b) was formed of a material having heat resistance to 1,850° C. (heating part 34a: 4 mm in diameter, conductive part 34b: 9 mm in diameter). The 10 heaters 34 were disposed in the furnace body 14, and a β-Ga₂O₃ crystal was produced. The heaters 34 after the production are shown in FIG. 6.

In the case where the heaters 34 of Example 1 were used, the heaters 34 after the crystal growth suffered one deformed heater 34 (deformation frequency: 1/8) and three broken heating parts 34a (breakage frequency: 3/16), as shown in FIG. 4A. After taking the heaters 34 out from the furnace body 14, the heaters 34 (heating parts 34a) each were rather brittle, and finally 8 heating parts 34a were broken after taking out from the furnace body 14 (breakage frequency: 8/16), as shown in FIG. 4B. However, the further production of a β-Ga₂O₃ crystal was possible in the state shown in FIG. 4A without exchanging (detaching) the heaters 34. In the conductive parts 34b, the attachment of powder that seemed to be caused by melting a part of the surface layer was confirmed. The degree of deformation and breakage of the heaters 34 in Example 1 was similar to the ordinary heaters 34 (as shown by the solid line arrows in FIG. 6, the heaters 34 suffered breakage at 6 sites in the state where the heater were disposed in the furnace body 14). Accordingly, even in the case where the heaters 34 of Example 1 were used, the deformation and breakage of the heaters 34 due to heat were suppressed to the similar degree as the ordinary ones while the conductive parts 34b were slightly deteriorated, which showed that the cost reduction was achieved.

The furnace body 14 in Reference Example had no furnace pipe 30, and the heat resistant material 14a constituting the outer wall of the furnace space 15 became deformable. Accordingly, in the heater 34 of Reference Example, the conductive part 34b was not sufficiently supported to cause positional deviation of the heating part 34a, resulting in breakage mainly at the tip of the heating part 34a.

In the case where the heaters 34 of Example 2 were used, the heaters 34 after the crystal growth suffered one deformed heater 34 (deformation frequency: 1/8) and one broken heating part 34a (breakage frequency: 1/16), as shown in FIG. 5A. After taking the heaters 34 out from the furnace body 14, the heaters 34 retained robust strength, and finally 2 heating parts 34a were broken after taking out from the furnace body 14 (breakage frequency: 2/16), as shown in FIG. 5B. It was thus shown that the heater 34 of Example 2 largely suppressed the deformation and breakage of the heater 34 as compared to the ordinary heater 34 of Reference Example and the heater 34 of Example 1. The heaters 34 shown in FIGS. 5A and 5B were those after the production of a β-Ga₂O₃ crystal multiple times, and the further production of a β-Ga₂O₃ crystal was possible in the state shown in FIG. 5A without exchanging (detaching) the heaters 34. As shown in FIG. 5B, furthermore, substantially no attachment of powder to the conductive part 34b occurred in the heater 34 of Example 2, which showed that the deterioration of the conductive part 34b was suppressed by protecting the portion from the base end to the connecting site to the conductive part 34b of the heating part 34a by the connecting part 34c.

The present invention is not limited to the embodiments described above, and various modifications may be made therein in such a range that does not deviate from the scope of the present invention. Particularly, a VB furnace has been described herein as an example, but the present invention may be applied to a VGF furnace using similarly a temperature gradient in the vertical direction. Furthermore, the present invention may be applied to an HB furnace and an HGF furnace using a temperature gradient in the horizontal direction, to which the sites where the deformation and breakage of the resistance heater tend to occur are common.

What is claimed is:

1. A production apparatus for a gallium oxide crystal comprising:
a furnace body constituted by a heat resistant material,
a crucible disposed in the furnace body, and
a heater disposed around the crucible,
the heater being a resistance heater including a heating part and a conductive part having a larger diameter than the heating part connected to each other, the heating part being constituted by a material having heat resistance to 1,850° C., the conductive part being constituted by a material having heat resistance to 1,800° C.

2. The production apparatus for a gallium oxide crystal according to claim 1, wherein
the heater includes the heating part that is connected to the conductive part via a connecting part formed to have a diameter that is larger than the heating part and smaller than the conductive part, constituted by a material having heat resistance to 1,850° C.

3. The production apparatus for a gallium oxide crystal according to claim 2, wherein
the heater has a ratio of a diameter (x) of the heating part, a diameter (y) of the connecting part, and a diameter (z) of the conductive part (x:y:z) that satisfies 3≤x≤9, 4≤y≤12, and 6≤z≤18 (provided that x<y<z).

4. The production apparatus for a gallium oxide crystal according to claim 3, wherein
the heater has a ratio of a diameter (x) of the heating part, a diameter (y) of the connecting part, and a diameter (z) of the conductive part (x:y:z) that satisfies y≤3x, z≤2y, and z≤4x (provided that x<y<z).

5. The production apparatus for a gallium oxide crystal according to claim 1, wherein
the heater is formed of molybdenum disilicide (MoSi₂).

6. The production apparatus for a gallium oxide crystal according to claim 1, wherein
the heater is provided in a linear shape from side view, in such a manner that the conductive part penetrates through an upper portion of the furnace body and is provided in the vertical direction in the furnace body, and the heating part is extended in the vertical direction at a tip of the conductive part in the furnace body.

7. The production apparatus for a gallium oxide crystal according to claim 1, wherein
the heater is provided in an L-shape from side view, in such a manner that the conductive part penetrates through a side part of the furnace body and is bent in the vertical direction in the furnace body, and the heating part is extended in the vertical direction at a tip of the conductive part in the furnace body.

8. The production apparatus for a gallium oxide crystal according to claim 1, wherein
the heater includes two conductive parts connected to the heating part at tips thereof formed in a U-shape,
the heating part has a diameter of 3 to 9 mm, and
the heating part has a bending width of less than 40 mm.
